(19) United States
(12) Patent Application Publication
(10) Pub. No.: US 2016/0181278 A1
(43) Pub. Date: Jun. 23, 2016

(54) ARRAY SUBSTRATE, METHOD FOR MANUFACTURING THE SAME, AND DISPLAY DEVICE

(71) Applicant: BOE TECHNOLOGY GROUP CO., LTD., Beijingv (CN)

(72) Inventors: Seungjin CHOI, Beijing (CN); Jing NIU, Beijing (CN); Shuang SUN, Beijing (CN); Fangzhen ZHANG, Beijing (CN)

(73) Assignee: BOE TECHNOLOGY GROUP CO., LTD., Beijing (CN)

(21) Appl. No.: 14/436,773

(22) PCT Filed: Aug. 14, 2014
(86) PCT No.: PCT/CN2014/084405

§ 371 Date: Apr. 17, 2015

(30) Foreign Application Priority Data
Mar. 28, 2014 (CN) 201410122807.2

(51) Int. Cl. H01L 27/12; G02F 1/1368; G02F 1/1362; H01L 33/42

(52) U.S. Cl. CPC H01L 27/124; H01L 27/1288; H01L 27/1262; H01L 33/42; G02F 1/1368; G02F 1/136286; G02F 2001/136295

(57) ABSTRACT

The present disclosure relates to the field of liquid crystal display technology, and provides an array substrate, its manufacturing method and a display device. The array substrate includes data lines, gate lines, and a plurality of pixel units defined by the data lines and the gate lines. Each of the plurality of the pixel unit includes a thin film transistor and a pixel electrode. The drain electrode includes a source/drain metal layer and an antioxidant conductive layer, the pixel electrode electrically contacts the antioxidant conductive layer, to realize electrical connection.

### CROSS-REFERENCE TO RELATED APPLICATION

This application claims a priority to Chinese Patent Application No. 201410122807.2 filed on Mar. 28, 2014, the disclosure of which is incorporated in its entirety by reference herein.

### TECHNICAL FIELD

The present disclosure relates to the field of liquid crystal display technology, in particular to an array substrate, a method for manufacturing the same, and a display device.

### BACKGROUND

A thin film transistor-liquid crystal display (TFT-LCD), being developed rapidly in recent years, has advantages of a small size, low power consumption and radiation free, and plays a leading role in the current market of a flat panel display.

A major structure of the TFT-LCD is a liquid crystal panel, which includes an array substrate and a color filtering substrate which are arranged oppositely to form a cell, and a liquid crystal molecule layer filled between the array substrate and the color filtering substrate. The array substrate is provided with data lines, gate lines and a plurality of pixel units defined by the data lines and the gate lines, each of the plurality of pixel unit includes a thin film transistor (TFT), and a pixel electrode. In the TFT, a gate electrode is electrically connected to the gate line, a source electrode is electrically connected to the data line, a drain electrode is electrically connected to the pixel electrode. The gate electrode and the gate line are formed by one same gate metal film layer; the source electrode, the drain electrode and the data line are formed by another same source/drain electrode film layer. The liquid crystal panel further includes a common electrode, an electrical field is generated between the common electrode and the pixel electrode, so as to drive liquid crystal molecules to deflect. The display principle of the TFT-LCD is that: a gate line driver circuit inputs a scanning signal into each line of the gate lines in turn, so as to turn on the TFTs line by line; in the case that a certain line of the TFTs are in on-state, a data line driver circuit inputs a pixel voltage into each column of the data lines, and the pixel voltage is applied to the pixel electrode via the source electrode, so as to generate a driving electric field between the common electrode and the pixel electrode, for driving the liquid crystal molecules to deflect, thereby to achieve display with a certain gray scale.

In the related art, in order to decrease pixel voltage consumption during transportation, the source/drain electrode is usually made of copper (Cu), so as to decrease resistance of the data line. However, the copper is easily to be oxidized. If the pixel electrode is manufactured after the drain electrode has been formed, copper oxide is formed on a surface of the drain electrode, resulting in poor electrical connection between the drain electrode and the pixel electrode, and poor display of the pixel unit, thereby to adversely affect display quality severely.

### SUMMARY

An object of the present disclosure is to provide an array substrate and its manufacturing method, so as to solve such problem that when the pixel electrode is manufactured after the drain electrode has been formed, copper oxide is formed on a surface of the drain electrode, resulting in a poor electrical connection between the drain electrode and the pixel electrode is poor, a poor display quality of the pixel unit.

The present disclosure provides in an embodiment an array substrate, including data lines, gate lines and a plurality of pixel units defined by the date lines and the gate lines, each of the plurality of pixel units including a thin film transistor and a pixel electrode, the pixel electrode being electrically connected to a drain electrode, wherein the drain electrode includes a source/drain metal layer and an antioxidant conductive layer, the pixel electrode electrically contacts the antioxidant conductive layer.

The present disclosure further provides in another embodiment a display device, including the above array substrate.

The present disclosure further provides in another embodiment a method for manufacturing an array substrate, including steps of:

forming a source/drain electrode film layer on a base substrate, performing a patterning process on the source/drain electrode film layer to form a data line, a source electrode and a drain electrode of a thin film transistor;

forming a first transparent conductive film layer on the base substrate with the data line, the source electrode and the drain electrode, performing a patterning process on the first transparent conductive film layer to form a pixel electrode,
wherein the step of forming the drain electrode further includes:
forming an antioxidant conductive film layer, performing a patterning process on the antioxidant conductive film layer to form an antioxidant conductive layer, the pixel electrode electrically contacting the antioxidant conductive layer.

The present disclosure has the following advantageous effects. According to the above embodiments, when the drain electrode of the thin film transistor is made of a source/drain metal easily to be oxidized, the drain electrode of the thin film transistor is configured to include a source/drain metal layer and an antioxidant conductive layer, and the pixel electrode electrically contacts the antioxidant conductive layer, so as to achieve electrical connection, and guarantee good electrical connection between the pixel electrode and the drain electrode, thereby to improve display quality of display.

### BRIEF DESCRIPTION OF THE DRAWINGS

In order to make the technical solutions in embodiments of the present disclosure or in related art more clearly, the drawings used in embodiments of the present disclosure or in related art will be briefly described below. Apparently, the following drawings only relate to some embodiments of the present disclosure, and based on these drawings, other drawings may also be obtained by one of ordinary skills in the art without any creative effort.

FIG. 1 is a schematic view of an array substrate according to an embodiment of the present disclosure;

FIG. 2 is a schematic view showing a cross-section along A-A′ direction in FIG. 1;

FIG. 3 is a schematic view showing a process of manufacturing an array substrate according to an embodiment of the present disclosure;

FIG. 4 is a schematic view showing a process of manufacturing an array substrate according to another embodiment of the present disclosure;

FIG. 5 is a schematic view showing a process of manufacturing an array substrate according to a yet another embodiment of the present disclosure; and

FIG. 6 is a schematic view showing a process of manufacturing an array substrate according to a still yet another embodiment of the present disclosure.

### DETAILED DESCRIPTION

In the related art, in a thin film transistor array substrate, when a data line is made of a source/drain metal easily to be oxidized (such as copper), in particular, in the case that a pixel electrode is manufactured by a single patterning process on a drain electrode, which has been formed by another single patterning process in advance, metallic oxide is formed on the surface of the drain electrode which is formed by the same source/drain electrode film layer with the data line, resulting in poor electrical connection between the drain electrode and the pixel electrode. For the above problem, the present disclosure provides in embodiments an array substrate and its manufactured method. According to embodiments of the present disclosure, in a thin film transistor, a drain electrode is configured to include a source/drain metal layer and an antioxidant conductive layer, a pixel electrode electrically contacting the antioxidant conductive layer, so as to achieve electrical connection, and guarantee good electrical connection between the pixel electrode and the drain electrode, thereby to improve display quality of display.

In an embodiment of the present disclosure, the electrical connection includes: 1) patterns of two conductive film layers are contacted directly; 2) patterns of two conductive film layers are contacted indirectly via an electrical connecting structure (such as a wire, or a via hole filled with conductive medium). The electrical contact between patterns of two conductive film layers is for achieving the electrical connection therebetween.

It should be noted that, on the array substrate according to embodiments of the present disclosure, a pattern of one film layer being located on a pattern of another film layer refers to that the one film layer is formed on base substrate of the array substrate prior to the other film layer. Similarly, a pattern of one film layer being located under a pattern of another film layer refers that the other film layer is formed the base substrate of the array substrate prior to the one film layer.

Specific embodiments of the present disclosure will be described in details hereinafter in conjunction with the drawings and the embodiments. The following embodiments are for illustrating the present disclosure, but not intended to limit the scope of the present disclosure.

### Embodiment 1

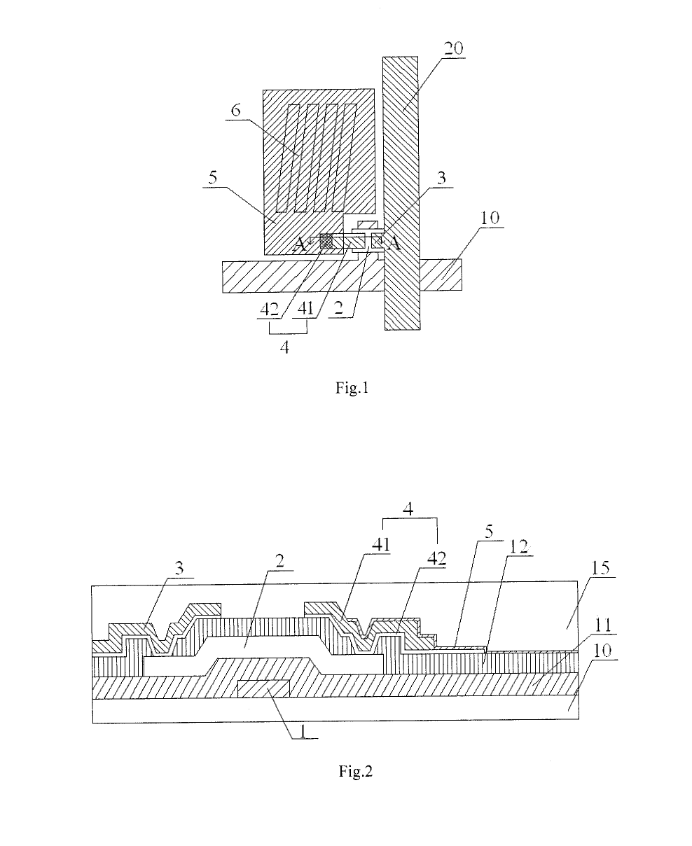

Referring to FIGS. 1 and 2, the present disclosure provides an array substrate, which includes the data lines 20, the gate lines 100, and a plurality of pixel units defined by the data lines 20 and the gate lines 100. Each of the plurality of pixel units includes a thin film transistor and the pixel electrode 5. The pixel electrode 5 is located on the drain electrode 4 of the thin film transistor, and electrically connected to the drain electrode 4. In specific, after the drain electrode 4 has been formed by a single patterning process, the pixel electrode 5 is then formed on the drain electrode 4 by another single patterning process.

The drain electrode 4 of the thin film transistor includes the source/drain metal layer 41 and the antioxidant conductive layer 42. In the present embodiment, the antioxidant conductive layer 42 is configured to electrically contact the pixel electrode 5, so as to guarantee good electrical connection between the pixel electrode 5 and the drain electrode 4. In some other embodiments, the pixel electrode 5 may also both electrically contact the antioxidant conductive layer 42 and electrically contact the source/drain metal layer 41.

During specific application, the antioxidant conductive layer may be made of a metal or an metal alloy having a low resistivity and hardly to be oxidized, for example, one or more selected from MoNb, MoW and MoTi.

In the drain electrode 4, the source/drain metal layer 41 may be lapped on the antioxidant conductive layer 42, resulting in a portion of the antioxidant conductive layer 42 to be exposed, which facilitates direct contact between the pixel electrode 5 on the drain electrode 4 and the antioxidant conductive layer 42, so as to achieve electrical connection therebetween. In specific, the source/drain metal layer 41 and the antioxidant conductive layer 42 may be formed at the same time by a single patterning process, so as to simplify the manufacturing process and lower production cost. In some other embodiments, the antioxidant conductive layer 42 may be formed by a single patterning process firstly, and then the source/drain metal layer 41 is formed by another single patterning process.

It should be noted that, according to embodiments of the present disclosure, a pattern of one film layer being lapped on a pattern of another film layer refers to that the other film layer and the one film lay are form on a base substrate in turn without any other film layer therebetween. At least a part of the pattern of the one film layer is configured to contact only a part of the pattern of the other film layer, so as to expose a rest part of the pattern of the other film layer.

In some other embodiments, the source/drain metal layer 41 may be also located under the antioxidant conductive layer 42, and the source/drain metal layer 41 and the antioxidant conductive layer 42 are formed at the same time by a single patterning process. As the antioxidant conductive film layer is formed right after the source/drain metal film layer is formed, it may effectively prevent the surface of the source/drain metal layer 41 being oxidized. In this case, the antioxidant conductive layer 42 may be located at a position corresponding to that of the source/drain metal layer 41, and located within a region where the source/drain metal layer 41 is located, i.e., the antioxidant conductive layer 42 may have boundaries corresponding to that of the source/drain metal layer 41, or may be located at a position inside the boundaries of the source/drain metal layer 41.

Because the data line is usually formed at the same time with the source electrode and the drain electrode of the thin film transistor by a single patterning process, in the present embodiment, the source electrode 3 also includes a source/drain metal layer and an antioxidant conductive layer, and the data line 20 also includes a source/drain metal layer and an antioxidant conductive layer.

The specific structure of the TFT array substrate in embodiments of the present disclosure will be illustrated in details hereinafter by taking a TFT array substrate of an ADS-mode display device as an example.

The Advanced Super Dimension Switch (ADS, also known as AD-SDS) refers to that: a multi-dimensional electric field is formed by combining an electric field, generated among edges of slit pixel electrodes (i.e., the pixel electrode has a plurality of slits extending in different directions) in a same plane, and an electric field, generated between a slit pixel electrode layer and a plate common electrode layer, so that all liquid crystal molecules between the slit pixel electrodes and above the pixel electrodes in a liquid crystal cell are deflected, thereby to improve liquid crystal work efficiency and increase transmittance efficiency. The ADS can improve image quality of a display device, has advantages of high resolution, high transmittance, low power consumption, wide viewing angle, high aperture ratio, low chromatic aberration, no push mura, and the like.

As shown in FIGS. 1 and 2, in the present embodiment, the TFT array substrate specifically includes:

the base substrate 10, being a transparent glass substrate or a transparent quartz substrate;

the gate electrode 1 and the gate line 100, formed on the base substrate 10;

the gate insulating layer 11, formed on the gate electrode 1 and the gate line 100;

the active layer pattern 2, which is formed on the gate insulating layer 11, corresponds to a position where the gate electrode 1 is located, and made of amorphous silicon or an oxide semiconductor;

the etch stopping layer 12, formed on the active layer pattern 2, and provided with a via hole above the active layer pattern 2;

the source electrode 3, the drain electrode 4 and the data line 20, formed on the etch stopping layer 12, wherein the source electrode 3 and the drain electrode 4 are configured to contact the active layer pattern 2 by via holes in the etch stopping layer 12, respectively; a portion of the active layer pattern 2 located between the source electrode 3 and the drain electrode 4 forms a channel of the thin film transistor; the drain electrode 4 includes the source/drain metal layer 41 and the antioxidant conductive layer 42, in which the source/drain metal layer 41 is lapped on the antioxidant conductive layer 42, resulting in a portion of the antioxidant conductive layer 42 to be exposed; and the source electrode 3 also includes a source/drain metal layer and an antioxidant conductive layer, the data line 20 also includes a source/drain metal layer and an antioxidant conductive layer;

the pixel electrode 5, formed on the drain electrode 4, and lapped on the source/drain metal layer 41 and the antioxidant conductive layer 42;

the passivation layer 15, formed on the pixel electrode 5; and

the common electrode 6, which is formed on the passivation layer 15 and located at a position corresponding to that of the pixel electrode 5, and includes a plurality of slits.

### Embodiment 2

The present embodiment provides a display device using the array substrate in the Embodiment 1. As the data line in the array substrate of the thin film transistor is made of the source/drain metal having a low resistivity and easily to be oxidized, eg. copper, it may lower transport resistance of pixel voltage; at the same time, because good electrical connection is guaranteed between the drain electrode and the pixel electrode, it may improve display quality of the display device.

The display device may be any products or members having a display function, e.g., a liquid crystal display panel, an electronic paper, an OLED panel, a mobile phone or a flat-panel PC, a TV, a display, a laptop, a digital photo frame, a navigator.

### Embodiment 3

Based on one same inventive concept, the present disclosure further provides in the present embodiment a method for manufacturing the array substrate in Embodiment 1. The method includes following steps of:

forming a source/drain electrode film layer on a base substrate; and

performing a patterning process on the source/drain electrode film layer, to form a data line, a source electrode and a drain electrode of a thin film transistor;

forming a first transparent conductive film layer on the base substrate with the data line, the source electrode and the drain electrode, performing a patterning process on the first transparent conductive film layer to form a pixel electrode, wherein the step of manufacturing a drain electrode of a thin film transistor further includes:

forming an antioxidant conductive film layer, performing a patterning process on the antioxidant conductive film layer to form an antioxidant conductive layer, wherein the drain electrode includes a source/drain metal layer and the antioxidant conductive layer, the pixel electrode electrically contacts the antioxidant conductive layer, to achieve electrical connection.

In the above steps, the drain electrode of the thin film transistor includes the source/drain metal layer and the antioxidant conductive layer; the pixel electrode is configured to electrically contact the antioxidant conductive layer to achieve electrical connection, so as to guarantee good electrical connection between the drain electrode and the pixel electrode, thereby to improve display quality of display.

In the drain electrode, the source/drain metal layer is lapped on the antioxidant conductive layer, resulting in a portion of the antioxidant conductive layer to be exposed, which facilitates direct contact between the pixel electrode located on the drain electrode and the antioxidant conductive layer, so as to achieve the electrical connection therebetween. In specific, the source/drain metal layer and the antioxidant conductive layer of the drain electrode may be formed by a single patterning process, thereby to simplify the manufacturing process and lower production cost.

Because the data line is usually formed at the same time with the source electrode and the drain electrode of the thin film transistor by a single patterning process, then the data line also includes a source/drain metal layer and an antioxidant conductive layer, and the source electrode also includes a source/drain metal layer and an antioxidant conductive layer.

In specific, the patterning process of forming a data line, a source electrode and a drain electrode of the TFT includes:

forming an antioxidant conductive film layer and a source/drain electrode film layer on a base substrate in turn;

coating photoresist on the source/drain electrode film layer, exposing, developing the photoresist using a half-tone or gray tone mask plate, so as to form a photoresist-totally-reserved area, a photoresist-half-reserved area and a photoresist-unreserved area, in which the photoresist-totally-reserved area at least corresponds to a region where the source/drain metal layer of the drain electrode, the data line and the source electrode are located, the photoresist-half-reserved area at least corresponds to a region where the exposed portion of antioxidant conductive layer of the drain electrode is located, and the photoresist-unreserved area corresponds to other regions;

etching the antioxidant conductive film layer and the source/drain electrode film layer corresponding to the photoresist-unreserved area using a wet etching process;

removing the photoresist on the photoresist-half-reserved area by an ashing process, etching the source/drain electrode film layer corresponding to the photoresist-half-reserved area; and peeling off the rest photoresist, to form the data line, the source electrode and the drain electrode.

In the above steps, the source/drain metal layer and the antioxidant conductive layer of the drain electrode are formed simultaneously by a single patterning process. In some other embodiments, it may also firstly form the antioxidant conductive layer of the drain electrode on the base substrate by a single patterning process, and then form the source/drain metal layer of the drain electrode on the base substrate with the antioxidant conductive layer by another patterning process.

The source/drain metal layer of the drain electrode may be located above the antioxidant conductive layer, or may be located under the antioxidant conductive layer. In the case that the source/drain metal layer of the drain electrode is located under the antioxidant conductive layer, it required to simultaneously form the source/drain metal layer and the antioxidant conductive layer of the drain electrode by a single patterning process. As the antioxidant conductive film layer is manufactured right after the source/drain metal film layer is formed, it may effectively prevent the surface of the source/drain metal layer of the drain electrode from being oxidized. In this case, the antioxidant conductive layer of the drain electrode may be located at a position corresponding to that of the source/drain metal layer, and located within a region where the source/drain metal layer is located, i.e., the antioxidant conductive layer may have boundaries corresponding to that of the source/drain metal layer, or may be located at a position inside the boundaries of the source/drain metal layer.

The TFT array substrate of the ADS display device further includes a common electrode, an electric field is generated between the common electrode and the pixel electrode to drive liquid crystal molecules to deflect. In the case that the pixel electrode is located on the drain electrode of the thin film transistor, the pixel electrode is lapped on the drain electrode so as to be electrically connected to the drain electrode. In the present disclosure, the pixel electrode is at least lapped on the antioxidant conductive layer of the drain electrode, in specific, the pixel electrode may be only lapped on the antioxidant conductive layer of the drain electrode, or may be both lapped on the antioxidant conductive layer of the drain electrode and lapped on the source/drain metal layer.

Accordingly, subsequent to the step of forming a pixel electrode on the base substrate, the method further includes:

forming a passivation layer on the base substrate with the pixel electrode;

forming a second transparent conductive film layer on the base substrate with the passivation layer; and

performing a patterning process on the second transparent conductive film layer to form a common electrode, wherein the common electrode includes a plurality of slits, and corresponds to a position where the pixel electrode is located.

Referring to FIGS. 1 to 6, the specific process of manufacturing the array substrate according to the present embodiment is shown as below.

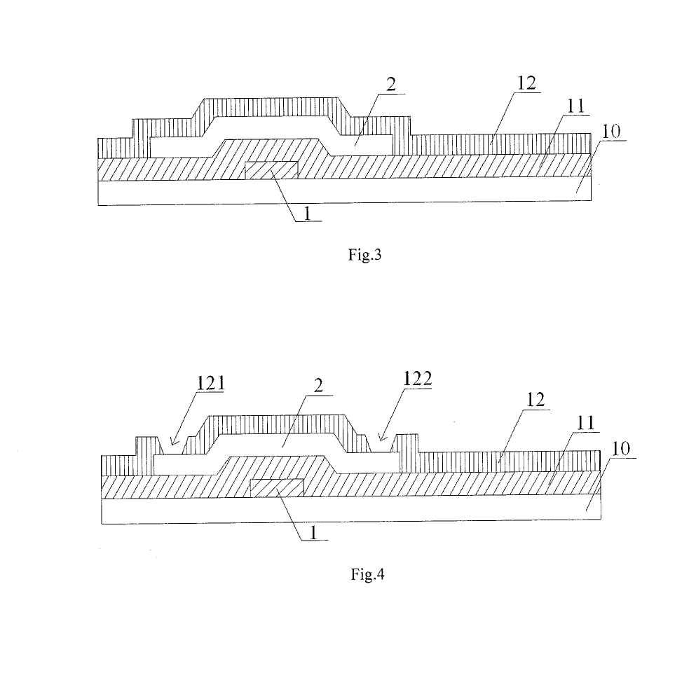

In Step S1, as shown as FIGS. 1 and 3, a gate metal film layer is formed on the base substrate 10 (such as a transparent glass substrate or a quartz substrate); and a patterning process is performed on the gate metal film layer to form the gate electrode 1 and the gate line 100, and then the gate insulating layer 11 is formed on the gate electrode 1 and the gate line 100. The gate metal may be Cu, Al, Ag, Mo, Cr, Nd, Ni, Mn, Ti, Ta, W, or other metals, or an alloy of these metals, the gate metal film layer may be of a single-layer structure or a multi-layer structure, such as Cu\Mo, Ti\Cu\Ti, Mo\Al\Mo. In specific, the gate insulating layer 11 may be formed on the gate electrode 1 and the gate line 100 by a coating process, a chemical deposit process, a sputtering process, or the like. The gate insulating layer 11 may be a composite layer consisting of two or three layers of a silicon dioxide layer, a silicon oxynitride layer and a silicon nitride layer. The silicon dioxide layer is preferably configured to be close to the active layer pattern 2, due to the less H content in SiO₂, thereby to avoid adverse effect on performance of a semiconductor including the active layer pattern.

In Step S2, as shown in FIGS. 1 and 3, an active layer is formed on the base substrate 10 after Step S1, a patterning process is performed on the active layer to form the active layer pattern 2. The active layer pattern 2 is made of a metallic oxide semiconductor, for example, one or more selected from amorphous IGZO, HIZO, IZO, ZnO, TiO₂, SnO and SdSnO.

In Step S3, as shown in FIG. 3, the etch stopping layer 12 is formed on the substrate 10 after Step S2. The etch stopping layer 12 is made of silicon nitride, silicon dioxide or silicon oxynitride.

In Step S4, a patterning process is performed on the etch stopping layer 12 using a general mask plate, to form a first via hole 121 and a second via hole 122. The first via hole 121 and the second via hole 122 are located on the active layer pattern 2, so as to expose the active layer pattern 2, as shown in FIG. 4.

In Step S5, as shown in FIG. 5, the antioxidant conductive film layer 13 and the source/drain electrode film layer 14 are formed on the base substrate 10 after Step S4 in turn. In specific, the antioxidant conductive film layer 13 and the source/drain electrode film layer 14 may be formed on the base substrate 10 in turn by a chemical deposit process, a sputtering process, or the like. The antioxidant conductive film layer 13 is made of a metal or a metal alloy having a low resistivity and hardly to be oxidized, for example, one or more selected from MoNb, MoW and MoTi. The source/drain electrode film layer 14 is made of metal copper having a low resistivity and easy to be oxidized.

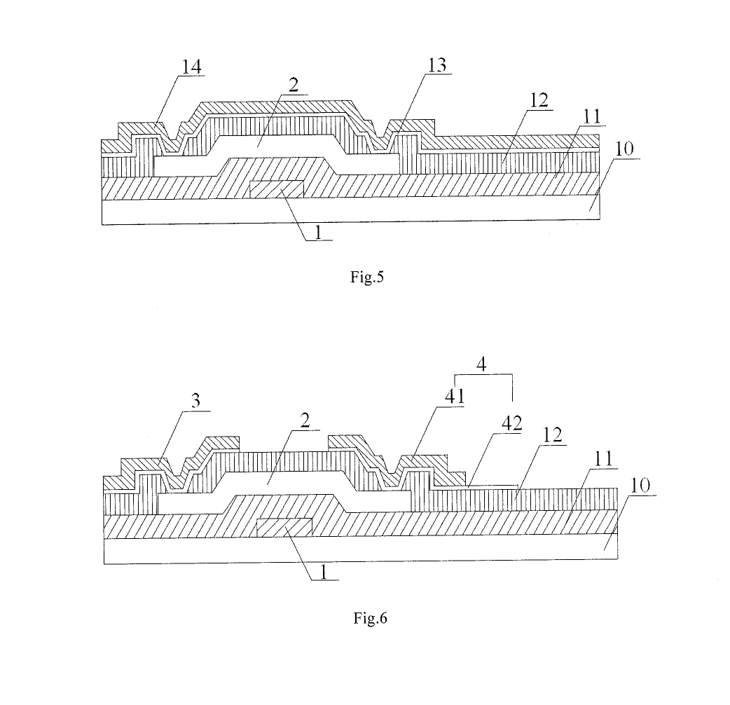

In Step S6, as shown in FIG. 1 and FIG. 6, a patterning process is performed on the antioxidant conductive film layer 13 and the source/drain electrode film layer 14, to form the source electrode 3, the drain electrode 4 and the data line 20. The source electrode 3 is electrically connected to the active layer pattern 2 through the first via hole 121, and the drain electrode is electrically connected to the active layer pattern 2 through the second via hole 122, as shown in FIG. 4.

In specific, the patterning process of forming the data line, the source electrode and the drain electrode specifically includes:

coating photoresist on the source/drain electrode film layer 14, exposing, developing the photoresist using a half-tone or gray tone mask plate, so as to form a photoresist-totally-reserved area, a photoresist-half-reserved area and a photoresist-unreserved area, in which the photoresist-totally-reserved area at least corresponds to a region where the data line 20, the source electrode 3 and the source/drain metal layer 41 of the drain electrode 4 are located, the photoresist-half-reserved area at least corresponds to a region where the exposed portion of antioxidant conductive layer 42 of the drain electrode 4 is located, and the photoresist-unreserved area corresponds to other regions;

etching the antioxidant conductive film layer and the source/drain electrode film layer corresponding to the photoresist-unreserved area by a wet etching process;

removing the photoresist on the photoresist-half-reserved area by an ashing process, and etching the source/drain electrode film layer corresponding to the photoresist-half-reserved area, in which the source/drain electrode film layer is preferably etched by an etching solution, the mixing a ratio of the etching solution and deoinized water is 2:1 or 1:1 to 1:5, which may decelerate etching of the source/drain metal; and

peeling off the rest photoresist, to form the source electrode 3, drain electrode 4 and the data line 20, in which the source electrode 3 also includes a source/drain metal layer and the antioxidant conductive layer, and the data line 20 also includes source/drain metal layer and the antioxidant conductive layer.

In Step S7, as shown in FIG. 2, a first transparent conductive film layer (such as ITO or IZO) is formed on the base substrate 10 after Step S6, then a patterning process is performed on the first transparent conductive film layer by a general mask plate, to form the pixel electrode 5. The pixel electrode 5 is lapped on the source/drain metal layer 41 and the antioxidant conductive layer 42 of the drain electrode 4.

In Step S8, as shown in FIG. 2, the passivation layer 15 is formed on the base substrate 10 after Step S7. The passivation layer 15 is made of silicon dioxide, silicon nitride or silicon oxynitride.

In Step S9, as shown in FIG. 1, a second transparent conductive film layer (such as ITO or IZO) is formed on the base substrate 10 after Step S8, and then a patterning process is performed on the second transparent conductive film layer using a general mask plate, to form the common electrode 6. The common electrode 6 includes a plurality of slits, and corresponds to a position where the pixel electrode 5 is located.

Then the process of manufacturing the array substrate is completed by Steps S1 to S9.

According to embodiments of the present disclosure, when the drain electrode of the thin film transistor is made of a source/drain metal easily to be oxidized, then the drain electrode of the thin film transistor is configured to include a source/drain metal layer and an antioxidant conductive layer, and the pixel electrode is configured to electrically contact the antioxidant conductive layer, so as to achieve electrical connection, and guarantee good electrical connection between the pixel electrode and the drain electrode, thereby to improve display quality of display.

The above are merely the preferred embodiments of the present disclosure. It should be appreciated that, a person skilled in the art may make further improvements and modifications without departing from the principle of the present disclosure, and these improvements and modifications shall also fall within the scope of the present disclosure.

1. An array substrate, comprising data lines, gate lines and a plurality of pixel units defined by the data lines and the gate lines, each of the plurality of pixel units comprising a thin film transistor and a pixel electrode, the pixel electrode being electrically connected to a drain electrode of the thin film transistor,
wherein the drain electrode comprises a source/drain metal layer and an antioxidant conductive layer, the pixel electrode electrically contacts the antioxidant conductive layer.

2. The array substrate according to claim 1, wherein in the drain electrode, the source/drain metal layer is lapped on the antioxidant conductive layer, to expose a portion of the antioxidant conductive layer.

3. The array substrate according to claim 2, wherein the pixel electrode is lapped on the source/drain metal layer and the antioxidant conductive layer of the drain electrode.

4. The array substrate according to claim 3, further comprising a common electrode which comprises a plurality of slits, wherein the common electrode is located above the pixel electrode, and a passivation layer is formed between the common electrode and the pixel electrode.

5. The array substrate according to claim 1, wherein a source electrode of the thin film transistor comprises a source/drain metal layer and an antioxidant conductive layer; and
the data line comprises a source/drain metal layer and an antioxidant conductive layer.

6. The array substrate according to claim 1, wherein the source/drain metal layer is made of a material including copper.

7. The array substrate according to claim 1, wherein the antioxidant conductive layer is made of one or more selected from MoNb, MoW and MoTi.

8. A display device, comprising the array substrate according to claim 1.

9. A method for manufacturing an array substrate, comprising steps of:
forming a source/drain electrode film layer on a base substrate, performing a patterning process on the source/drain electrode film layer to form a data line, a source electrode and a drain electrode of a thin film transistor;
forming a first transparent conductive film layer on the base substrate with the data line, the source electrode and the drain electrode, performing a patterning process on the first transparent conductive film layer to form a pixel electrode,
wherein the step of forming the drain electrode further comprises:
forming an antioxidant conductive film layer, performing a patterning process on the antioxidant conductive film layer to form an antioxidant conductive layer, the pixel electrode electrically contacting the antioxidant conductive layer.

10. The method according to claim 9, wherein in the drain electrode, the source/drain metal layer is lapped on the antioxidant conductive layer, to expose a portion of the antioxidant conductive layer.

11. The method according to claim 10, wherein the step of forming a data line, a source electrode and a drain electrode of a thin film transistor comprises:
forming the antioxidant conductive film layer and the source/drain electrode film layer on the base substrate in turn;
coating photoresist on the source/drain metal layer;
exposing and developing the photoresist using a gray tone or half-tone mask plate, to form a photoresist-totally-reserved area, a photoresist-half-reserved area and a photoresist-unreserved area, wherein the photoresist-totally-reserved area at least corresponds to a region where the source/drain metal layer of the drain electrode, the data line and the source electrode are located, the photoresist-half-reserved area at least corresponds to a region where exposed portion of the antioxidant conductive layer of the drain electrode is located, and the photoresist-unreserved area corresponds to other regions;
etching the antioxidant conductive film layer and the source/drain electrode film layer corresponding to the photoresist-unreserved area;
removing the photoresist on the photoresist-half-reserved area by an ashing process, and etching the source/drain electrode film layer corresponding to the photoresist-half-reserved area; and
peeling off the rest photoresist to form the data line, the source electrode and the drain electrode of the thin film transistor.

12. The method according to claim 9, subsequent to the step of forming a pixel electrode, the method further comprising:
forming a passivation layer on the base substrate with the pixel electrode;
forming a second transparent conductive film layer on the base substrate with the passivation layer; and
performing a patterning process on the second transparent conductive film layer to form a common electrode, wherein the common electrode comprises a plurality of slits.

13. The method according to claim 9, wherein prior to the step of forming the data line, the source electrode and the drain electrode, the method further comprising:
forming a gate metal film layer on the substrate, performing a patterning process on the gate metal film layer to form a gate line and a gate electrode;
forming a gate insulating layer on the gate electrode and the gate line;
forming an active film layer on the gate insulating layer, performing a pattering process on the active film layer to form an active layer; and
forming an etch stopping film layer on the active layer, performing a patterning process on the etch stopping film layer, to form via holes at positions corresponding to the source electrode and the drain electrode, respectively, wherein the source electrode and the drain electrode are electrically connected to the active layer through the via holes.

14. The method according to claim 9, wherein the source/drain metal layer is made of a material including copper.

15. The method according to claim 9, wherein the antioxidant conductive layer is made of one or more selected from MoNb, MoW and MoTi.

16. The method according to claim 10, subsequent to the step of forming a pixel electrode, the method further comprising:
forming a passivation layer on the base substrate with the pixel electrode;
forming a second transparent conductive film layer on the base substrate with the passivation layer; and
performing a patterning process on the second transparent conductive film layer to form a common electrode, wherein the common electrode comprises a plurality of slits.

17. The method according to claim 10, wherein prior to the step of forming the data line, the source electrode and the drain electrode, the method further comprising:
forming a gate metal film layer on the substrate, performing a patterning process on the gate metal film layer to form a gate line and a gate electrode;
forming a gate insulating layer on the gate electrode and the gate line;
forming an active film layer on the gate insulating layer, performing a pattering process on the active film layer to form an active layer; and
forming an etch stopping film layer on the active layer, performing a patterning process on the etch stopping film layer, to form via holes at positions corresponding to the source electrode and the drain electrode, respectively, wherein the source electrode and the drain electrode are electrically connected to the active layer through the via holes.

18. The method according to claim 10, wherein the source/drain metal layer is made of a material including copper.

19. The method according to claim 10, wherein the antioxidant conductive layer is made of one or more selected from MoNb, MoW and MoTi.
